(19) United States
(12) Patent Application Publication
(10) Pub. No.: US 2026/0178808 A1
(43) Pub. Date: Jun. 25, 2026

(54) SYSTEM MAP EQUIVALENCE IN INTEGRATED CIRCUIT DESIGNS

(71) Applicant: ARTERIS, INC., Campbell, CA (US)

(72) Inventor: Yaron SEMIAT, Saint Maximin la Sainte Baume (FR)

(73) Assignee: ARTERIS, INC., Campbell, CA (US)

(21) Appl. No.: 18/986,851

(22) Filed: Dec. 19, 2024

(51) Int. Cl. G06F 30/3323; G06F 30/327

(52) U.S. Cl. CPC G06F 30/3323; G06F 30/327

(57) ABSTRACT

A computer-implemented design method includes creating a first elaborated design of an electronic system having a set of valid mode combinations, creating a second elaborated design of the system, creating a first system map from the first elaborated design, and creating a second system map from the second design. The method is implemented using a design tool. In some embodiments, the design tool includes a trained machine learning model. The first system map includes an address map for each valid mode combination of interest, and the second system map includes an address map for each valid mode combination of interest. If the first and second system maps are not equivalent, the second elaborated design is corrected prior to running a simulation on the second elaborated design.

### TECHNICAL FIELD

The present technology is in the field of electronic computer-aided design of integrated circuits.

### BACKGROUND

During design of a system-on-chip (SoC) or other modern integrated circuit (IC), a system architect generates a specification that relates to requirements of the integrated circuit. The specification may provide a chip definition, technology, domains and layout for the integrated circuit. An elaborated model of the integrated circuit is then created. Intellectual Property (IP) blocks are selected from the architect's library, configurable components are assembled from the IP blocks, and interconnections are made between the components.

After an initial SoC design is generated, the SoC design may be modified. Modifications may include adding components, adding instances, removing components, removing instances, changing the hierarchy of instances, changing connectivity between elements, changing parameters of instances, and so on. The modifications may continue until the system architect is satisfied with the architecture.

If an error is made in a design modification, that error might not be revealed until a simulation is performed. The error would be corrected, and the simulation would be repeated. However, simulations are computationally expensive and relatively slow. Moreover, simulations might not revel certain errors.

### SUMMARY

In accordance with various embodiments and aspects herein, a computer-aided design method includes creating a first elaborated design of an electronic system having a set of valid mode combinations, creating a second elaborated design of the system, creating a first system map from the first elaborated design, and creating a second system map from the second design. The first system map includes an address map for each valid mode combination of interest, and the second system map includes an address map for each valid mode combination of interest. If the first and second system maps are not equivalent, the second elaborated design is corrected prior to running a simulation on the second elaborated design.

In accordance with various embodiments and aspects herein, a computer system includes a processing unit, and computer-readable memory configured with a computer-aided design tool that, when executed, causes the processing unit to check system map equivalence of first and second elaborated designs of an integrated circuit having N initiators and P valid mode combinations of interest. An outer loop is performed for each initiator n=1 to N. An inner loop is performed for each mode combination p=1 to P. The inner loop includes generating a first resolved address map_{n,p} with respect to elements along a path of the p^{th} mode combination in the first elaborated design, generating a second resolved address map_{n,p} with respect to elements along a path of the p^{th} mode combination in the second elaborated design, and determining whether the first resolved address map_{n,p} is identical to the second resolved address map_{n,p}. Any non-equivalence is identified prior to running a simulation on the second elaborated design.

In accordance with various embodiments and aspects herein, computer-readable memory is encoded with instructions that, when executed, cause a processing unit to process first and second elaborated designs of an integrated circuit having N initiators and P valid mode combinations of interest. Processing includes running an outer loop for each initiator n=1 to N. The processing further includes running an inner loop for each mode combination p=1 to P. The inner loop generates a first resolved address map_{n,p} with respect to elements along a path of the p^{th} mode combination in the first elaborated design, generates a second resolved address map_{n,p} with respect to elements along a path of the p^{th} mode combination in the second elaborated design, and checks whether the first resolved address map_{n,p} is identical to the second resolved address map_{n,p}.

### BRIEF DESCRIPTION OF THE DRAWINGS

In order to understand the invention more fully, reference is made to the accompanying drawings. The invention is described in accordance with the aspects and embodiments in the following description with reference to the drawings or figures (FIG.), in which like numbers represent the same or similar elements. Understanding that these drawings are not to be considered limitations in the scope of the invention, the presently described aspects and embodiments and the presently understood best mode of the invention are described with additional detail through use of the accompanying drawings.

FIG. 1 is an illustration of an electronic system such as a system-on-chip having an interconnect.

FIG. 2 is an illustration of a method of designing an electronic system such as a system-on-chip in accordance with various aspects and embodiments herein.

FIG. 3 is an illustration of a method of checking system map equivalence between first and second designs of an electronic system in accordance with various aspects and embodiments herein.

FIG. 4 is an illustration of comparing resolved address maps of first and second designs to determine system map equivalence in accordance with various aspects and embodiments herein.

FIG. 5 is an example of address transformations during creation of an address map in accordance with various aspects and embodiments herein.

FIG. 6 is an illustration of a method of creating an address map in accordance with various aspects and embodiments herein.

FIG. 7 is an illustrated example of an original design of an electronic system,

FIG. 8 is an illustrated example of a correct modification of the original design of FIG. 7.

FIG. 9 is an illustrated example of an incorrect modification of the original design of FIG. 7.

FIG. 10 is an illustration of a computer system programmed with a tool for performing functions including system map equivalence checking in accordance with various aspects and embodiments herein.

FIG. 11 is an illustration of an example of a valid mode combination for a path between an initiator and a target.

### DETAILED DESCRIPTION

The following describes various examples of the present technology that illustrate various aspects and embodiments of the invention. Generally, examples can use the described aspects in any combination. All statements herein reciting principles, aspects, and embodiments as well as specific examples thereof, are intended to encompass both structural and functional equivalents thereof. The examples provided are intended as non-limiting examples. Additionally, it is intended that such equivalents include both currently known equivalents and equivalents developed in the future, i.e., any elements developed that perform the same function, regardless of structure.

It is noted that, as used herein, the singular forms “a,” “an” and “the” include plural referents unless the context clearly dictates otherwise. Reference throughout this specification to “one embodiment,” “an embodiment,” “certain embodiment,” “various embodiments,” or similar language means that a particular aspect, feature, structure, or characteristic described in connection with the embodiment is included in at least one embodiment of the invention.

Thus, appearances of the phrases “in one embodiment,” “in at least one embodiment,” “in an embodiment,” “in certain embodiments,” and similar language throughout this specification may, but do not necessarily, all refer to the same embodiment or similar embodiments. Furthermore, aspects and embodiments of the invention described herein are merely exemplary, and should not be construed as limiting of the scope or spirit of the invention as appreciated by those of ordinary skill in the art. All statements herein reciting principles, aspects, and embodiments of the invention are intended to encompass both structural and functional equivalents thereof. It is intended that such equivalents include both currently known equivalents and equivalents developed in the future. Furthermore, to the extent that the terms “including”, “includes”, “having”, “has”, “with”, or variants thereof are used in either the detailed description and the claims, such terms are intended to be inclusive in a similar manner to the term “comprising.”

“IP” or Intellectual Property refers to a reusable unit of logic or functionality or a cell or a layout design. Each IP may have a memory map, hosting registers and memory elements arranged under address blocks. Each memory map is accessible through a bus interface. The IP may be described in one or more IEEE 1685 standard files.

The IEEE 1685 standard describes an XML schema for meta-data documenting IP used in the development, implementation, and verification of electronic systems. Standardized meta-data forms include components, systems, bus interfaces and connections, abstractions of those buses, and details of the components including address maps, register and field descriptions. One such standard is the IP-XACT 1685-2022 standard.

As used herein, a “design” of an electronic system refers to the components of the system and the interconnections between the components. The design may be represented by IP-XACT files.

A “component” represents a single IP block that can be instantiated as a single entity in a design. A component document provides information about a component, such as such as interfaces of an IP (e.g., configurable parameters, registers, ports, and grouping of ports into bus interfaces); views of an IP (e.g., RTL and TLM descriptions); and files implementing each view (e.g., Verilog, VHDL, and SystemC files).

As used herein, a memory map” refers to a mapping of addressable memory elements of a component. The memory map defines memory regions, address ranges, and associated attributes (e.g., read/write permission and data widths). A memory map may include different types of memory map elements, including registers, address blocks, banks, and subspace maps.

A “bus definition” specifies a type of bus. A bus definition document describes signals in the bus interface and constraints that apply to those signals. This includes signal names, direction, width, and usage.

A “bus interface” references an addressable bus definition to make a link to a component address space. Interface characteristics, including ports, direction (input/output), signals, protocols, address range, and timing constraints can be specified using IP-XACT.

A “transaction” may refer to a request transaction or a response transaction. A transaction may contain one or more destination addresses for one or more components the transaction is sent to. The address may include the address of a sub-component (e.g., an individual register within an array of registers, internal memory, etc.).

A “bridge” refers to a component that allows access to several memory maps through a single interface.

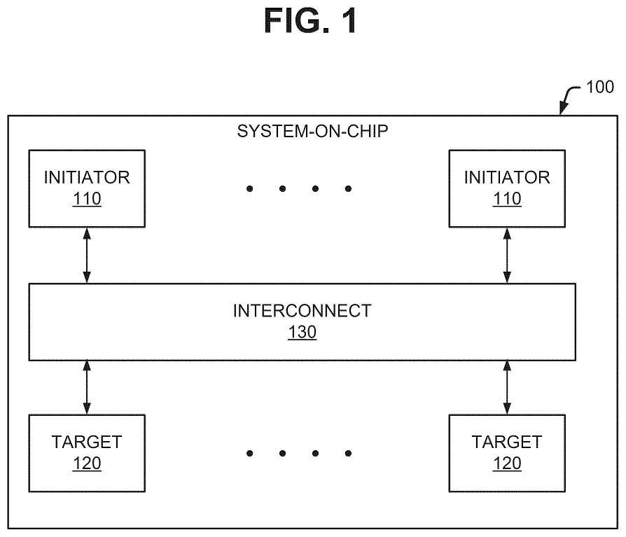

Reference is made to FIG. 1, which illustrates an electronic system 100 such as a system-on chip (SoC). The system 100 includes a number N of initiators 110 and a number T of targets 120. Examples of the initiators 110 include, without limitation, central processing units (CPUs), graphics processing units (GPUs), digital signal processors (DSPs), and direct memory access (DMA) engines. Examples of the targets 120 include, without limitation, system memory, and peripheral devices.

The initiators 110 communicate with the targets 120 via an interconnect 130. Each request transaction sent by an initiator 110 may include an address of a target 120. A target 120 may respond to a request transaction by sending a response transaction. The response transaction includes the address of the initiator that sent the request transaction.

One example of the interconnect 130 is a network-on-chip (NoC). A NoC typically includes a plurality of network interface units (NIUs) and a transport interconnect. Each initiator 110 is coupled to the transport interconnect via a corresponding NIU, and each target 120 is coupled to the transport interconnect via a corresponding NIU. Each NIU is configured to convert the protocol used by its corresponding core into a transport protocol used inside the NoC. The transport protocol is typically based on the transmission of packets. The transport interconnect transports packets between the NIUs. The transport interconnect includes components such as switches, adapters, and buffers. Switches may be used to route flows of traffic between the initiators 110 and the targets 120. Adapters may be used to deal with various conversions between data width, clock and power domains. Buffers may be used to insert pipelining elements to span long distances, or to store packets to deal with rate adaptation between fast senders and slow receivers or vice-versa.

The system 100 has a number L of modes of operation. The behavior of each component may be dependent on the modes of operation. As a first example, the system 100 has a low power mode in which access to one peripheral is allowed, and a full power mode in which access to twelve peripherals is allowed. As a second example, the system 100 has a normal mode of operation where memory component A and memory component B are accessible, and a low power mode where only memory component A is accessible. During different modes of operation, the routing of transactions may be different.

The system 100 may have different valid combinations of modes. Consider an example in which the system 100 has three modes: M1, M2 and M3. The set of mode combinations is {M1, M2, M3, M1-M2, M1-M3, M2-M3, M1-M2-M3}. However, not all of the mode combinations in the set might be valid. For the mode combination to be valid, all modes going through a path between an initiator 110 and a target 120 are active.

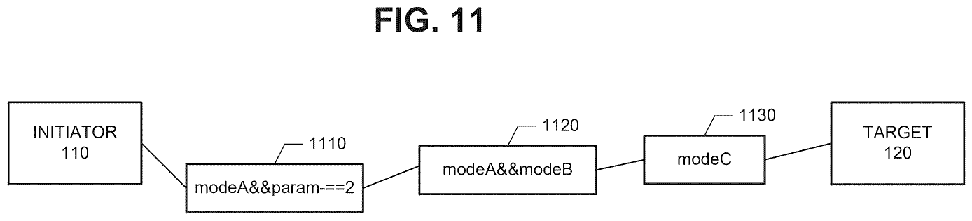

FIG. 11 illustrates an example of a valid mode combination for a path between an initiator 110 and a target 120. There are first, second and third components 1110, 1120 and 1130, respectively, along the path. The mode condition of this combination is the logical AND of the mode conditions of the components 1110, 1120 and 1130. The mode combination is valid if mode A of the first component 1110 is active (modeA=1), param==2, mode B of the second component 1120 is also active (modeA&&modeB=1), and mode C of the third component 1130 is active (modeC=1).

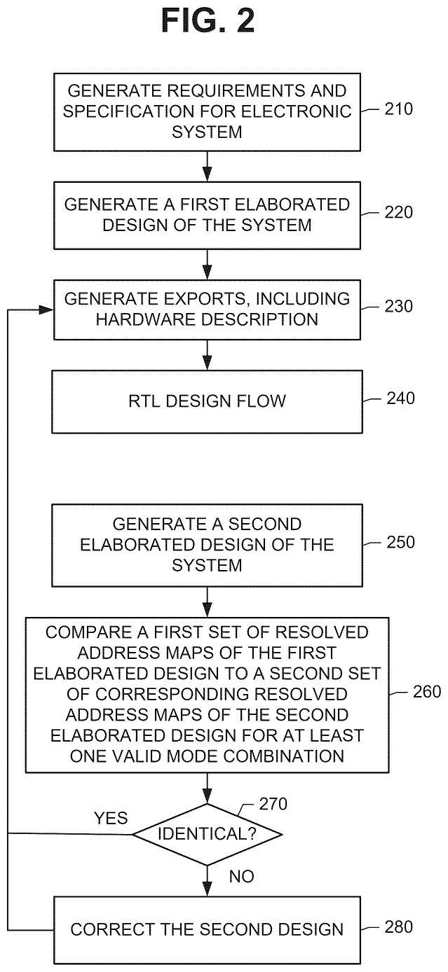

Reference is made to FIG. 2, which illustrates a method of designing an electronic system such as a system-on-chip. At block 210, requirements for the system are generated. The requirements may be dictated by marketing, sales, customer intent, etc. Also at block 210, a system architect generates a specification that relates to the requirements. The specification provides a chip definition, technology, domains and layout for the system.

At block 220, an elaborated model or design of the system is created. IP blocks are selected from the architect's library, configurable components are assembled from the IP blocks, interconnections are made between the IP blocks, and parameters of the components are resolved. The interconnections may include wires and bridges. Various routing components (e.g., interconnects and bridges) may be used to route and process transactions between the components. An interconnect can have several input ports for accepting transactions, determining the output port based on address, and modifying the address. As another example, a bridge may have a single input port and a single output port, and it may perform operations on the incoming transaction, and modify the address to create a new address for the outgoing transaction.

The system may be modelized in IP-XACT. An IP-XACT model describes the hierarchical composition of the system using components, the interfaces of each component accessing its memory map, the interconnection between the component interfaces, bridge operations between initiator and target interfaces (e.g., re-assigning address ranges within the target into the initiator space), and dependencies of the components in configurable parameters.

At block 230, exports are generated from the design. The exports may include a hardware description of the design, such as a Register Transfer Level (RTL) design.

At block 240, RTL design flow is performed. RTL design flow includes simulations, synthesis, and place and route. The simulations are performed on the hardware description of the design to determine whether the system fulfills the specifications.

Later, at block 250, a second elaborated design is generated. In some instances, the second elaborated design may be a modification of the first elaborated design. Modifications may include adding components, adding instances, removing components, removing instances, changing the hierarchy of instances, and changing connectivity between components. Modifications may also include changing parameters of the components in the design. Modifications may be driven by other considerations. For example, a change may be based on modification flux and/or specific business knowledge.

Modes may be added to the second design. For example, a new IP mode is introduced in which there is a new set of registers, but with a support of a subset for legacy users. Subsystems may be created. For example, subsystems may be created for reasons of clock domains and power domains. Subsystems may also be created for tiles and chiplets implementations, such as a multi-chip. For example, subsystems implemented in chiplets may have addressable memory that is mapped on a system map of the entire system. Bridging logic may be used to model the interconnect to the chiplets.

The first and second designs are not limited to consecution design versions. For instance, the first design could be a baseline design that was created during early stages of system design, and the second design may be a later modification of the system design.

In some embodiments, the tool includes machine learning (ML) models that are used to automate certain aspects of the design process. The ML models are trained using data and feedback. For instance, one or more ML models are used to suggest routing patterns, placement of components and component sizing. The ML model also identifies bottlenecks in circuit designs. If simulations have already been performed, the ML models may collect outputs of the previous simulations, which may be in the form of feedback to the ML model, and suggest improvements to sizing, routing patterns and placement of components.

At block 260, a first set of resolved address maps of the first elaborated design is compared to a second set of corresponding resolved address maps of the second elaborated design with respect to at least one valid mode combination. For example, for the first elaborated design, there is a first resolved address map for a first valid mode combination, a second resolved address map for a second valid mode combination, and so on. And for the second elaborated design, there is a first resolved address map for the first valid mode combination, a second resolved address map for the second valid mode combination, and so on. During comparison, the first resolved address map of the first elaborated design is compared to the first resolved address map of the second elaborated design, the second resolved address map of the first elaborated design is compared to the second resolved address map of the second elaborated design, and so on.

As used herein, the terms “system map” and “system-level address map” are interchangeable and refer to the set of resolved address maps of a design. A comparison of the system maps of different designs is referred to as “system map equivalence checking.” If the first set of resolved address maps is identical to the second set of resolved address maps, the first and second designs are said to be “system map equivalent.”

At block 270, if the first and second system maps are identical, control is returned to block 230. New exports are created for the second elaborated design, and new simulations are performed.

If the second system map is not identical to the first system map, this indicates that modification introduced a functional regression with regards to the second system map. As but one example, connectivity for one of the mode combinations in the second design was incorrectly changed.

At block 280, the errors are corrected and control is returned to block 230. New exports of the corrected elaborated design are created, and new simulations are performed.

The method of FIG. 2 makes it faster and more efficient to identify and correct non-equivalence. Non-equivalence is identified and errors are corrected before performing a simulation. In contrast, if errors are identified during a simulation, the errors are corrected and the simulation is rerun. Simulations are computationally expensive. Moreover, simulations are error prone. If they don't cover all of the addressable elements, then they risk not detecting the functional regression. The method of FIG. 2 wins significant time and reduces risks for system verification and firmware development.

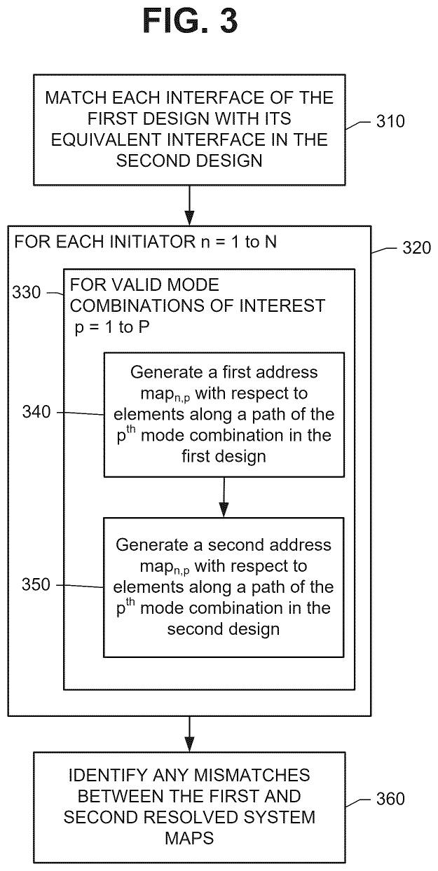

Reference is now made to FIG. 3, which illustrates a computationally efficient method of identifying mismatches between resolved address maps of a first design and corresponding resolved address maps of a second design.

The method of FIG. 3 is described in connection with a system-on-chip having N initiators, and P valid mode combinations of interest. The mode combinations of interest may be a full set of valid mode combinations (P=S) or a subset of the full set (P<S), or even a single valid mode combination P=1).

Prior to performing the method, the first and second designs have been elaborated (for instance, at block 220 of FIG. 2). There is a first set of configurable parameters for the first design, and a second set of configurable parameters for the second design. The first set of configurable parameters is applied to the first design to produce an elaborated first design; and the second set of configurable parameters is applied to the second design to produce an elaborated second design.

At block 310, each interface of the first design is matched with its equivalent interface in the second design. Consider the example in which the first and second designs are generated by two different parties, and the two different parties use different names for initiator interfaces. The initiator interfaces in the first design are matched with the initiator interfaces in the second design.

In some embodiments, the tool includes a trained ML classification model that is used to perform the matching. The ML classification model is trained on a training dataset that has groups of parameters for different components. The parameter groups may be labeled with standardized initiator interface names. After the trained ML classification model is applied to one or both designs, a comparison is made.

At block 320, an outer loop is performed, in which the N initiators are iterated over. For each initiator n=1 to N, block 330 is performed.

At block 330, an inner loop is performed, in which the valid mode combinations are iterated over. For each valid mode combination p=1 to P, a first resolved address map_{n,p} is generated with respect to elements along a path of the p^{th} mode combination in the first design (block 340); and a second resolved address map_{n,p} is generated with respect to elements along a path of the p^{th} mode combination in the second design (block 350).

At block 360, any mismatches between the first and second system maps are identified. For instance, this determination may be made after each n, p or it may be made after all resolved address maps up to the N^{th} initiator and P^{th} mode combination have been generated, or it may be made at some other time.

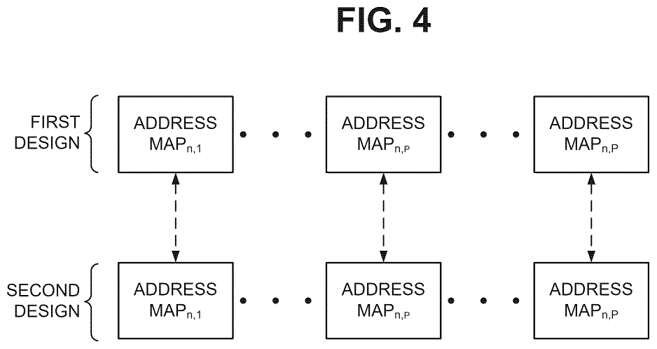

FIG. 4 illustrates a comparison of address maps for the inner loop. For the n^{th} initiator, a total of P address maps are generated for the first design, and a total of P address maps are generated for the second design. The first map_{n,1} of the first design is compared to the first map_{n,1} of the second design (as indicated by the double arrow), the second map_{n,2} of the first design is compared to the second map_{n,2} of the second design, and so on.

If comparisons are performed over all of the valid mode combinations for all of the initiators, there will be N*P comparisons. However, in some instances, it might be desirable to check only a particular valid mode combination. Then only N comparisons would be performed (one for each initiator) for that particular valid mode combination.

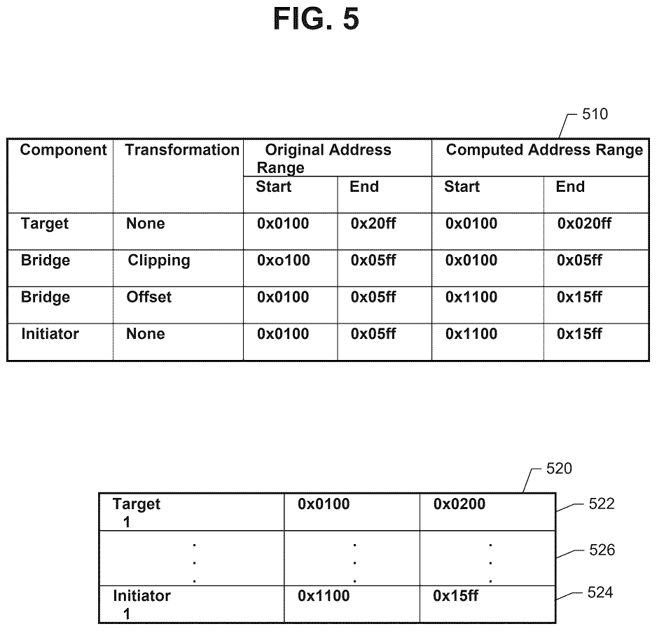

Reference is made to FIG. 5, which illustrates a table 510 showing a set of address transformations for a path from an initiator to a bridge to a target. The target has an original address range of 0×0100 to 0×20ff. The bridge performs two transformations: a clipping operation from 0×0100 to 0×05ff, and an offset operation of 0×1000. The clipping operation will mask addresses above 0×05ff. Therefore, the available range of target addresses becomes 0×0100 to 0×05ff. The offset operation transforms the available range of target addresses from 0×1100 to 0×15ff.

FIG. 5 also illustrates the resulting address table 520 for the path from the initiator to the bridge to the target. A first entry 522 includes target name and instance in a first column, and the range in a second column. A second entry 524 includes the initiator name and instance in the first column, and the address range in the right column. If a component is not selected from the IP blocks, the entry may include just the address range. There may be additional entries 526 for components between the initiator and the target. In this particular example, there is only the bridge. In other instances, there may be multiple bridges and other components.

In addition to the address ranges being identical, two resolved address maps are considered identical if their properties are equivalent, and if all registers within each slice of the system map are equivalent. In some embodiments, register contents within a slice range are equivalent if for each memory mapped address, a sub division into ‘fields’ is equivalent (e.g., every field has bitOffset within the containing register, and a bit-width); and all field properties are equivalent (e.g., Software access policy, Hardware update rules, Volatile, Testable, Supported value range, Reset source, Reset value, and Clock domain).

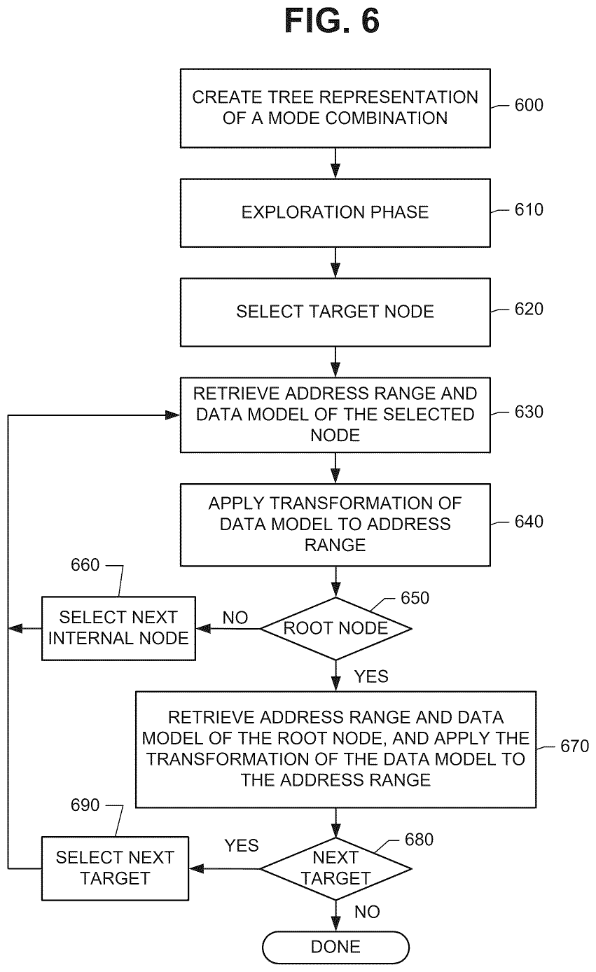

Reference is made to FIG. 6, which illustrates a method of generating a resolved address map. The method of FIG. 6 is described in greater detail in assignee's US Publication No. 2023/0025288.

At block 600, a tree representation of a mode combination is created by using interconnect information, where the n^{th} initiator is a root node, a target is an external or leaf (child) node, and each port is an internal node containing information such as hierarchical component identification within the design, local addressable elements, local address ranges, capability to perform operations on addresses (e.g., address range), and memory of node (e.g., memory, registers). The information may further include issuance capabilities (e.g., the number of address bits in a transaction issued by an initiator), acceptance capabilities (e.g., the number of address bits in the transaction received by a target), and one or more transfer functions from input port to output port(s), such as bridge transfer functions (e.g., masking, clipping, adding offset), interconnect transfer functions, and component transfer functions.

At block 610, an exploration phase is performed for a root node. All relevant targets are detected. As used herein, relevant targets refer to all targets that are connected on a path to the root node. If no targets are detected, there will be no address map for that root node.

At block 620, a child node representing a target is selected, and at blocks 630-670, a tree traversal back to the root node is performed. At block 630, the address range and a data model of the selected node are retrieved. At block 640, an address map entry is calculated for the selected node by applying the transformation of the data model to the address range of the selected node.

At block 650, if the next node is not the root node (that is, the node of the n^{th} initiator), the tree traversal continues. At block 660, the next internal node is selected, and control is returned to block 630.

Internal nodes are processed in this manner until the root node is encountered at block 650. At block 670, the address range and the data model of the root node are retrieved, and the transformation in the data model is applied to the address range of the root node.

At block 680, if there is another target, a child node representing the next target is selected, and control is returned to block 630. This method continues until all relevant targets on a path to the initiator are processed.

In some embodiments, each entry may be added to the resolved address map as the tree is being traversed. In other embodiments, all of the map entries may be combined to create the resolved address map after the tree traversal has been completed.

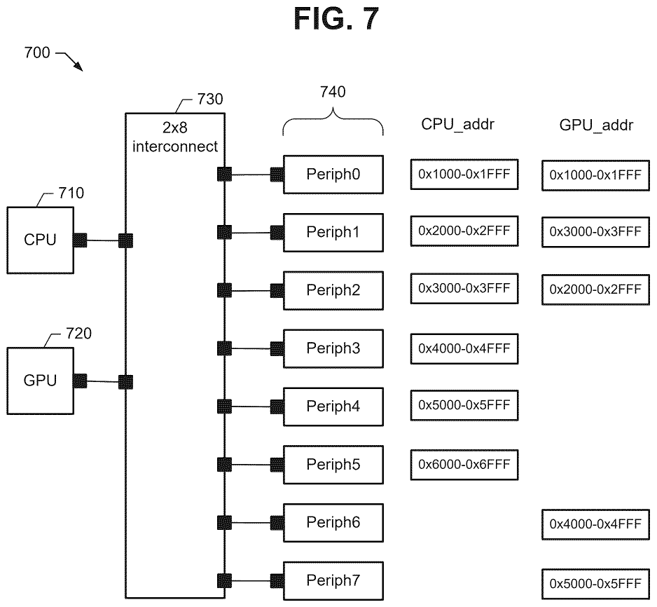

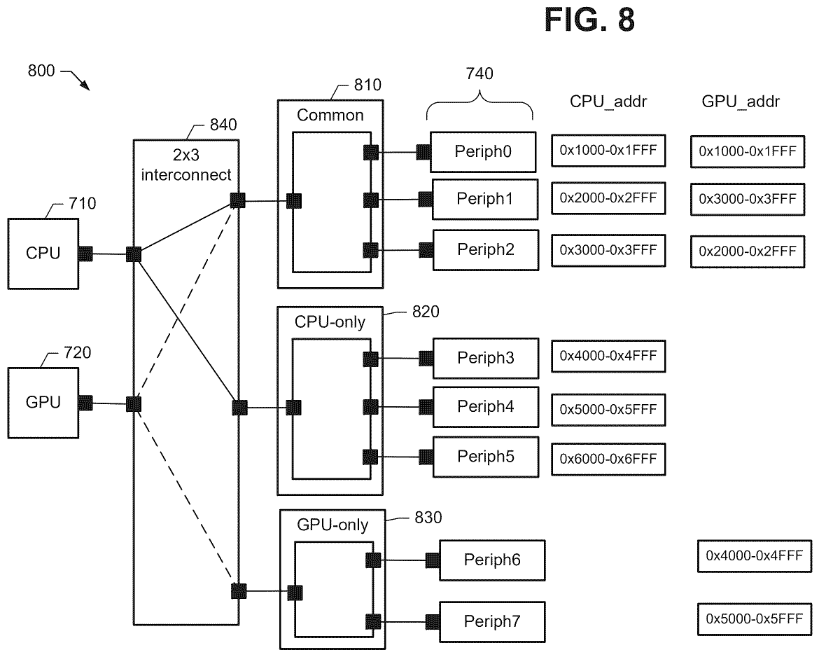

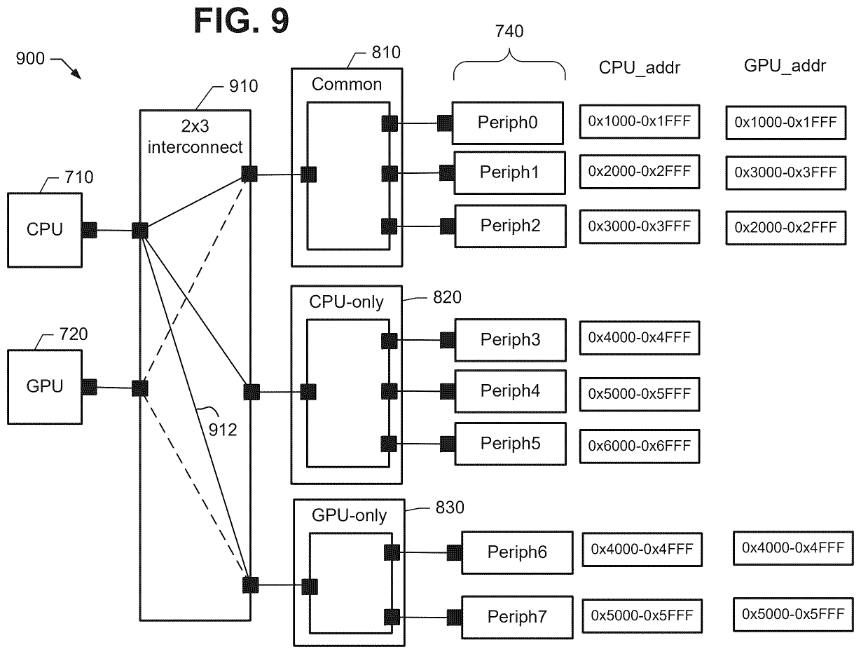

FIGS. 7, 8 and 9 illustrate simple examples of designs that are system map equivalent and non-equivalent. The original design of FIG. 7 is system map equivalent to the modified design of FIG. 8. The modified design of FIG. 9 is not system map equivalent to the designs of FIGS. 7 and 8. The examples are characterized as simple because in practice a design may have hundreds of peripherals and, in the future, even thousands of peripherals.

FIG. 7 shows a design 700 in which, a CPU 710 and a GPU 720 are coupled to eight peripheral devices 740 (Periph0 to Periph7) by a 2×8 interconnect 730. Peripheral devices Periph0, Periph1 and Periph2 are addressable by both the CPU 710 and the GPU 720 (although not necessarily at the same addresses). Peripheral devices Periph3, Periph4 and Periph5 are addressable only by the CPU 710, and peripheral devices Periph6 and Periph7 are addressable only by the GPU 720. The address ranges of the peripheral devices Periph0 to Periph5 are indicated in the column labeled CPU_addr. The address ranges of the peripheral devices Periph0 to Periph2 and Periph6 to Periph7 are indicated in the column labeled GPU_addr.

FIG. 8 shows a modification of the design 700. In the modified design 800, the CPU 710 and the GPU 720 are connected to a common bridge 810, a CPU-only bridge 820, and a GPU-only bridge 830 by a 2×3 interconnect 840. Peripheral devices Periph0, Periph1 and Periph2 are coupled to the common bridge 810. Peripheral devices Periph3, Periph4 and Periph5 are coupled to the CPU-only bridge 820. Peripheral devices Periph6 and Periph7 are coupled to the GPU-only bridge 830.

The system map for the design 700 of FIG. 7 is the same as the system map for the design 800 of FIG. 8. Both designs 700 and 800 “see” the peripherals 740 in the same way.

FIG. 9 shows another modification of the design 700. The modified design 900 of FIG. 9 is similar to the modified design 800 of FIG. 8, except that a design error was made: a wire 912 connects the third egress port of the interconnect 910 to the first ingress port, thus exposing Periph6 and Periph7 to the CPU 710 (they are supposed to be only accessible to the GPU 720).

The system map of the design 900 of FIG. 9 is not equivalent to the system map of the design of FIG. 7. Due to the additional wire in the design of FIG. 9, the CPU 710 of FIG. 9 sees more peripherals than the CPU 710 of FIG. 7.

If an RTL description is generated from the design 900, this error can be detected by the system map equivalence checking. The alternative, finding this error during simulations, would be very time consuming and far less computationally efficient.

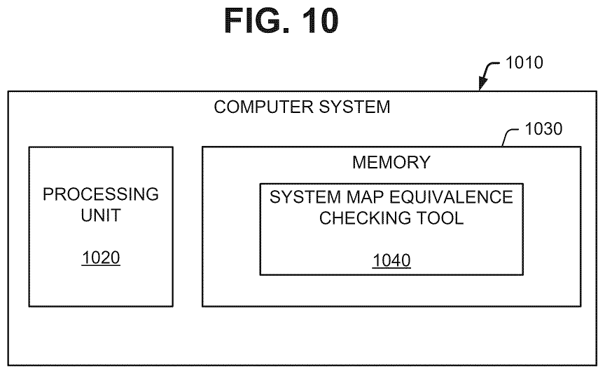

FIG. 10 shows a computer system 1010 including a processing unit 1020 and computer-readable memory 1030 that stores a computer-aided design tool 1040 that performs functions including system map equivalence checking as described herein. In some embodiments, the tool 1040 may be configured as a standalone application, In some embodiments, the tool 1040 may be integrated with an electronic computer-aided design system that is configured to generate and modify the designs. In some embodiments, the electronic computer-aided design system may also be configured to perform RTL design flow including the simulations.

Certain examples have been described herein and it will be noted that different combinations of different components from different examples may be possible. Salient features are presented to better explain examples; however, it is clear that certain features may be added, modified and/or omitted without modifying the functional aspects of these examples as described.

Certain methods according to the various aspects of the invention may be performed by instructions that are stored upon a non-transitory computer readable medium. The non-transitory computer readable medium stores code including instructions that, if executed by one or more processors, would cause a system or computer to perform steps of the method described herein. The non-transitory computer readable medium includes: a rotating magnetic disk, a rotating optical disk, a flash random access memory (RAM) chip, and other mechanically moving or solid-state storage media. Any type of computer-readable medium is appropriate for storing code comprising instructions according to various example.

Various examples are methods that use the behavior of either or a combination of machines. Method examples are complete wherever in the world most constituent steps occur. For example, IP elements or units include: processors (e.g., CPUs or GPUs), random-access memory (RAM—e.g., off-chip dynamic RAM or DRAM), a network interface for wired or wireless connections such as ethernet, WiFi, 3G, 4G long-term evolution (LTE), 5G, and other wireless interface standard radios. The IP may also include various I/O interface devices, as needed for different peripheral devices such as touch screen sensors, geolocation receivers, microphones, speakers, Bluetooth peripherals, and USB devices, such as keyboards and mice, among others. By executing instructions stored in RAM devices processors perform steps of methods as described herein.

Descriptions herein reciting principles, aspects, and embodiments encompass both structural and functional equivalents thereof. Elements described herein as coupled have an effectual relationship realizable by a direct connection or indirectly with one or more other intervening elements.

Practitioners skilled in the art will recognize many modifications and variations. The modifications and variations include any relevant combination of the disclosed features. Descriptions herein reciting principles, aspects, and embodiments encompass both structural and functional equivalents thereof. Elements described herein as “coupled” or “communicatively coupled” have an effectual relationship realizable by a direct connection or indirect connection, which uses one or more other intervening elements. Embodiments described herein as “communicating” or “in communication with” another device, module, or elements include any form of communication or link and include an effectual relationship. For example, a communication link may be established using a wired connection, wireless protocols, near-filed protocols, or RFID.

The scope of the invention, therefore, is not intended to be limited to the exemplary embodiments shown and described herein. Rather, the scope and spirit of present invention is embodied by the appended claims.

1. A computer-aided design method comprising:
creating a first elaborated design of an electronic system having a set of valid mode combinations;
creating a second elaborated design of the system;
creating a first system map from the first elaborated design, the first system map including an address map for each valid mode combination of interest;
creating a second system map from the second design, the second system map including an address map for each valid mode combination of interest; and
if the first and second system maps are not equivalent, correcting the second elaborated design prior to running a simulation on the second elaborated design.

2. The method of claim 1, wherein the second elaborated design is a later modification of the first elaborated design.

3. The method of claim 1, wherein the first and second designs are system map equivalent if each address map in the first system map and its corresponding address map in the second system map are identical with respect to all properties and all register contents.

4. The method of claim 1, wherein each address map includes an address range of an initiator, an address range of a target, and address ranges of all relevant internal nodes on a path between the initiator and the target.

5. The method of claim 1, further comprising:
generating exports including a register transfer level (RTL) description of the first elaborated design;
performing RTL design flow with the RTL description of the first elaborated design;
generating an RTL description of the second elaborated design only after system map equivalence has been shown; and
performing RTL design flow with the RTL description of the second elaborated design.

6. The method of claim 1, wherein the first and second elaborated designs each has N initiators; and wherein creating the first and second system maps and determining system map equivalence includes:
for each initiator n=1 to N:
for each mode combination of interest p=1 to P:
generating a first resolved address map_{n,p} with respect to elements along a path of a p^{th} mode combination in the first elaborated design;
generating a second resolved address map_{n,p} with respect to elements along a path of the p^{th} mode combination in the second elaborated design; and
determining whether the first resolved address map_{n,p} is identical to the second resolved address map_{n,p}.

7. The method of claim 6, wherein the electronic system is a system on chip including a network-on-chip (NoC).

8. The method of claim 7, wherein generating each resolved address map_{n,p} includes:
creating a tree representation where an n^{th} initiator is a root node, each target is a leaf node, and each port of each NoC component is an internal node;
performing an exploration phase for the root node to detect all relevant leaf nodes; and
for each leaf node, performing a tree traversal back to the root node, wherein each tree traversal includes calculating an address map entry for each traversed node.

9. The method of claim 8, wherein when a node is traversed, an address range and a data model of the traversed node are retrieved, transformations of the data model are applied to the address range, and the address range after transformation is included in the address map entry of the traversed node.

10. The method of claim 7, further comprising using a trained machine learning model to match initiator interfaces in the second design with initiator interfaces in the first design prior to creating the first system map and second system map and determining the system map equivalence.

11. A computer system comprising a processing unit; and computer-readable memory configured with a computer-aided design tool that, when executed, causes the processing unit to:
check system map equivalence of first and second elaborated designs of an integrated circuit having N initiators and P valid mode combinations of interest, including:
performing an outer loop for each initiator n=1 to N:
performing an inner loop for each mode combination of interest p=1 to P:
generating a first resolved address map_{n,p} with respect to elements along a path of a p^{th} mode combination in the first elaborated design;
generating a second resolved address map_{n,p} with respect to elements along a path of a p^{th} mode combination in the second elaborated design; and
determining whether the first resolved address map_{n,p} is identical to the second resolved address map_{n,p};
wherein any non-equivalence is identified prior to running a simulation on the second elaborated design.

12. The system of claim 11, wherein the integrated circuit is a system on chip including a network-on-chip (NoC).

13. The system of claim 12, wherein generating each resolved address map_{n,p} includes:
creating a tree representation where a n^{th} initiator is a root node, each target is a leaf node, and each port of each NoC component is an internal node;
performing an exploration phase for the root node to detect all relevant leaf nodes; and
for each leaf node, performing a tree traversal back to the root node, wherein each tree traversal includes calculating an address map entry for each traversed node.

14. The system of claim 13, wherein when a node is traversed, an address range and a data model of the traversed node are retrieved, transformations of the data model are applied to the address range, and the address range after transformation is included in the address map entry of the traversed node.

15. The system of claim 11, wherein the first resolved address map_{n,p} and the second resolved address map_{n,p} are identical with respect to all properties and all register contents.

16. The system of claim 11, wherein the processing unit is further configured to:
generate exports including a register transfer level (RTL) description of the first elaborated design;
perform RTL design flow with the RTL description of the first elaborated design;
generate an RTL description of the second elaborated design only after system map equivalence has been shown; and
perform RTL design flow with the RTL description of the second elaborated design.

17. An article comprising computer-readable memory encoded with instructions that, when executed, cause a processing unit to process first and second elaborated designs of an integrated circuit having N initiators and P valid mode combinations of interest, including:
running an outer loop for each initiator n=1 to N:
running an inner for each mode combination p=1 to P:
generating a first resolved address map_{n,p} with respect to elements along a path of a p^{th} mode combination in the first elaborated design;
generating a second resolved address map_{n,p} with respect to elements along a path of a p^{th} mode combination in the second elaborated design; and
checking whether the first resolved address map_{n,p} is identical to the second resolved address map_{n,p}.

18. The article of claim 17, wherein the integrated circuit further includes a plurality of targets and an interconnect for facilitating communication between the initiators and the targets; and wherein generating each resolved address map_{n,p} includes:
creating a tree representation where an n^{th} initiator is a root node, each target is a leaf node, and each port of each interconnect component is an internal node;
performing an exploration phase for the root node to detect all relevant leaf nodes; and
for each leaf node, performing a tree traversal back to the root node, wherein each tree traversal includes calculating an address map entry for each traversed node.

19. The article of claim 18, wherein when a node is traversed, an address range and a data model of the traversed node are retrieved, transformations of the data model are applied to the address range, and the address range after transformation is included in the address map entry of the traversed node.

20. The article of claim 18, wherein each address map_{n,p} includes an initiator address range, a target address range of a target, and address ranges of relevant components of the interconnect.
